(19) United States
(12) Patent Application Publication
(10) Pub. No.: US 2015/0295540 A1
(43) Pub. Date: Oct. 15, 2015

(54) OUTPHASING POWER AMPLIFIER HAVING UNBALANCED DRIVE POWER

(71) Applicant: AURIGA MEASUREMENT SYSTEMS, LLC, Chelmsford, MA (US)

(72) Inventors: John Muir, North Chelmsford, MA (US); Yusuke Tajima, Acton, MA (US)

(21) Appl. No.: 14/684,957

(22) Filed: Apr. 13, 2015

Related U.S. Application Data
(60) Provisional application No. 62/061,423, filed on Oct. 8, 2014.
(60) Provisional application No. 61/978,382, filed on Apr. 11, 2014.

(51) Int. Cl. H03F 1/02; H03F 3/19; H03F 3/21; H03F 1/42

(52) U.S. Cl. CPC H03F 1/0205; H03F 1/42; H03F 3/19; H03F 3/211; H03F 2200/451; H03F 2200/36; H03F 2203/21106

(57) ABSTRACT

Various methods and apparatus for operating an outphasing amplifier comprising first and second amplifiers to achieve wider bandwidth and higher efficiency of operation of the outphasing amplifier are disclosed.

### RELATED APPLICATIONS

The present application claims priority under 35 U.S.C. §119(e) to U.S. Provisional Application Ser. No. 61/978,382 filed on Apr. 11, 2014, entitled OUTPHASING POWER AMPLIFIER HAVING UNBALANCED DRIVE POWER; and U.S. Provisional Application Ser. No. 62/061,423 filed on Oct. 8, 2014, entitled OUTPHASING POWER AMPLIFIER HAVING UNBALANCED DRIVE POWER, each of which is hereby incorporated herein by reference in its entirety.

### FIELD OF THE INVENTION

The subject matter described herein relates generally to radio frequency (RF) circuits and, more particularly, to techniques and circuits for operation of RF amplifier circuits.

### BACKGROUND

Many modern communications applications require the transmission of signals having a varying envelope with a high peak-to-average ratio. To transmit such signals, it is important to use an RF amplifier or transmitter that is efficient over a wide dynamic range. Thus, it is desirable for the amplifier efficiency to be high under both average drive power and peak drive power conditions. In some applications, the difference between peak and average power levels can be as high as 10 dB or more.

When a signal envelope varies up to 10 dB, the optimum output impedance to achieve maximum efficiency in a power amplifier can vary dramatically. If the output load impedance stays constant while the envelope varies, inefficient amplifier operation will result. This is one reason that traditional power amplifier designs provide poor efficiency performance when used in high peak-to-average applications.

Efficiency of the RF amplifier over a wide dynamic range is critical for transmitting a signal with a varying envelope with a high peak-to-average ratio. Efficiency must be kept high under average power drive to the amplifier while, at the same time, the amplifier must be capable of transmitting the peak power. The difference between the two levels (peak and average) can be as much as 10 dB.

High efficiency over the required frequency band is also critical for the amplifier to operate as a transmitter for communication supporting various platforms. High efficiency operation over a wide dynamic range in a wide communication band is a challenging goal that a communication amplifier is required to meet.

There is a need for techniques and circuits that are capable of providing efficient amplifier operation under high peak-to-average ratio conditions.

### SUMMARY

Techniques, systems, and circuits described herein relate to the use of operating an outphasing amplifier comprising first and second amplifiers to achieve wider bandwidth and higher efficiency operation of the outphasing amplifier. One aspect of the method includes controlling input signal levels to each of the first and second amplifiers independently and asymmetrically to achieve nonsymmetrical drive to each of the first amplifier and second amplifier of the outphasing amplifier. Another aspect of the method includes independently adjusting a gate bias of the first amplifier and the second amplifier so that a leading phase amplifier is more pinched off and a lagging phase amplifier is less pinched off to achieve nonsymmetrical drive to the first amplifier and the second amplifier of the outphasing amplifier. Another aspect of the method includes independently controlling input pulse widths of a first input signal to the first amplifier and a second input signal to the second amplifier to achieve nonsymmetrical drive to the first amplifier and the second amplifier of the outphasing amplifier. Another aspect of the method includes providing the first and second amplifiers in the outphasing amplifiers as different sized amplifiers.

In one embodiment a method of operating an outphasing amplifier comprising first and second amplifiers to achieve wider bandwidth and higher efficiency operation of the outphasing amplifier, comprises controlling input signal levels to each of the first and second amplifiers independently and asymmetrically to achieve nonsymmetrical drive to each of the first amplifier and second amplifier of the outphasing amplifier.

This embodiment may further comprise providing the first and second amplifiers in the outphasing amplifiers as different sized amplifiers. Aspects of this embodiment may further comprise independently adjusting a gate bias of each the first and second amplifiers so that a leading phase amplifier is more pinched off and a lagging phase amplifier is less pinched off. Aspects of this embodiment may further comprise independently controlling input pulse widths of a first input signal to the first amplifier and a second input signal to the second amplifier to achieve nonsymmetrical drive to the first amplifier and the second amplifier of the outphasing amplifier.

Another embodiment of a method of operating an outphasing amplifier comprising first and second amplifiers to achieve wider bandwidth and higher efficiency operation of the outphasing amplifier, comprises independently adjusting a gate bias of the first amplifier and the second amplifier so that a leading phase amplifier is more pinched off and a lagging phase amplifier is less pinched off to achieve nonsymmetrical drive to the first amplifier and the second amplifier of the outphasing amplifier.

This embodiment may further comprise providing the first amplifier and the second amplifier in the outphasing amplifier with different sizes. Aspects of this embodiment may further comprise controlling input signal levels to each of the first and second amplifiers independently and asymmetrically to achieve nonsymmetrical drive to each of the first amplifier and second amplifier of the outphasing amplifier. Aspects of this embodiment may further comprise independently controlling input pulse widths of a first input signal to the first amplifier and a second input signal to the second amplifier to achieve nonsymmetrical drive to the first amplifier and the second amplifier of the outphasing amplifier.

Another embodiment of a method of operating a pulse-driven outphasing amplifier comprising first and second amplifiers to achieve wider bandwidth and higher efficiency operation of the pulse-driven outphasing amplifier, comprises independently controlling input pulse widths of a first input signal to the first amplifier and a second input signal to the second amplifier to achieve nonsymmetrical drive to the first amplifier and the second amplifier of the outphasing amplifier.

This embodiment may further comprise independently adjusting a gate bias of the first amplifier and the second amplifier so that a leading phase amplifier is more pinched off and a lagging phase amplifier is less pinched off to achieve nonsymmetrical drive to the outphasing amplifier. Aspects of this embodiment may further comprise providing the first amplifier and the second amplifier in the outphasing amplifiers with different sizes.

Another embodiment of a method of operating an outphasing amplifier, where the amplitude modulation is accomplished by controlling the differential phase of the two signals driving two amplifiers, the method comprises adjusting gate bias of the two amplifiers independently where the leading phase amplifier is more pinched off and the lagging phase amplifier is less pinched off to achieve nonsymmetrical drive to the outphasing combiner.

Another embodiment of a method of operating an outphasing amplifier, where the amplitude modulation is accomplished by controlling the differential phase of the two signals driving two amplifiers, comprises adjusting gate bias of the two amplifiers independently where the leading phase amplifier is more pinched off and the lagging phase amplifier is less pinched off to achieve nonsymmetrical drive to the outphasing combiner, and controlling input signal levels of the amplifiers having low input power when low output power is required and high input power when high output power is required.

Another embodiment of a method of operating an outphasing amplifier, where the amplitude modulation is accomplished by controlling the differential phase of the two signals driving two amplifiers, comprises adjusting gate bias of the two amplifiers independently where the leading phase amplifier is more pinched off and the lagging phase amplifier is less pinched off to achieve nonsymmetrical drive to the outphasing combiner, controlling input signal levels of the amplifiers having low input power when low output power is required and high input power when high output power is required, and two amplifiers in the outphasing amplifier have different sizes.

Another embodiment of a method of method of operating an outphasing amplifier, where the amplitude modulation is accomplished by controlling the differential phase of the two signals driving two amplifiers, comprises controlling input signal levels of each amplifier independently and asymmetrically to achieve nonsymmetrical drive to the outphasing combiner.

Another embodiment of a method of method of operating a pulse-driven outphasing amplifier, where the amplitude modulation is accomplished by controlling the differential position of the two pulse signals driving two amplifiers, comprises adjusting gate bias of the two amplifiers independently where the leading phase amplifier is more pinched off and the lagging phase amplifier is less pinched off to achieve nonsymmetrical drive to the outphasing combiner.

Another embodiment of a method of operating a pulse-driven outphasing amplifier, where the amplitude modulation is accomplished by controlling the differential position of the two pulse signals driving two amplifiers, comprises adjusting gate bias of the two amplifiers independently where the leading phase amplifier is more pinched off and the lagging phase amplifier is less pinched off to achieve nonsymmetrical drive to the outphasing combiner, and modulating an input pulse width of the two input signals to achieve smaller width for smaller output power and wider pulse for higher output power.

Another embodiment of a method of operating a pulse-driven outphasing amplifier, where the amplitude modulation is accomplished by controlling the differential position of the two pulse signals driving two amplifiers, comprises adjusting gate bias of the two amplifiers independently where the leading phase amplifier is more pinched off and the lagging phase amplifier is less pinched off to achieve nonsymmetrical drive to the outphasing combiner, and Modulating an input pulse width of the two input signals to achieve smaller width for smaller output power and wider pulse for higher output power, and two amplifiers in the outphasing amplifiers have different sizes.

Another embodiment of a method of operating a pulse-driven outphasing amplifier, where the amplitude modulation is accomplished by controlling the differential position of the two pulse signals driving two amplifiers, comprises controlling input pulse width of the two input signals independently to achieve nonsymmetrical drive to the outphasing combiner.

### BRIEF DESCRIPTION OF THE DRAWINGS

The foregoing features may be more fully understood from the following description of the drawings in which:

FIG. 1 illustrates a circuit diagram of one example of a Class E amplifier;

FIG. 2 illustrates an outphasing amplifier circuit having two amplifiers operating at maximum power that are combined through a low-loss combiner;

FIG. 3 illustrates the combiner as illustrated in FIG. 2 can be made from a balun as shown in FIG. 3;

FIG. 4 illustrates an equivalent circuit of an outphasing amplifier;

FIGS. 5A-5B illustrate a plot of the inverse of output conductance (1/G_{L}) and output power as a function of differential phase φ for the outphasing amplifier;

FIG. 6 illustrates a plot of load impedance contours for the power added efficiency for two drive power levels for the outphasing amplifier;

FIGS. 7A-7B illustrate a plot of drain efficiency of the outphasing amplifier as a function of output power of the outphasing amplifier at different frequencies;

FIGS. 8A-8B illustrate a plot of the real and imaginary parts of the output load for the outphasing amplifier as a function of V₂₀/V₁₀;

FIG. 9A-9B illustrate schematically the drive level of amplifiers of the outphasing amplifier as a function of input signal levels;

FIG. 10A-10B illustrate the impact of input control to the two amplifiers on the back-off efficiency of the outphasing amplifier over a frequency band;

FIGS. 11A-11B illustrate schematically the asymmetric output signal levels as a function of drive power level, for the outphasing amplifier having the different bias conditions set at pinch-off for PA1 and above pinch-off for PA2; and

FIG. 12 illustrates asymmetric output power characteristics for the outphasing amplifier as a function of input signal magnitude.

### DETAILED DESCRIPTION

Techniques, systems, and circuits described herein relate to the use of operating an outphasing amplifier comprising first and second amplifiers to achieve wider bandwidth and higher efficiency operation of the outphasing amplifier. One aspect of the method includes controlling input signal levels to each of the first and second amplifiers independently and asymmetrically to achieve nonsymmetrical drive to each of the first amplifier and second amplifier of the outphasing amplifier. Another aspect of the method includes independently adjusting a gate bias of the first amplifier and the second amplifier so that a leading phase amplifier is more pinched off and a lagging phase amplifier is less pinched off to achieve nonsymmetrical drive to the first amplifier and the second amplifier of the outphasing amplifier. Another aspect of the method includes independently controlling input pulse widths of a first input signal to the first amplifier and a second input signal to the second amplifier to achieve nonsymmetrical drive to the first amplifier and the second amplifier of the outphasing amplifier. Another aspect of the method includes providing the first and second amplifiers in the outphasing amplifiers as different sized amplifiers.

Class E is a class of operation where the output load to the amplifier is designed to provide the optimum load at the fundamental frequency while the load provides reactive conditions at the harmonics of the fundamental frequency. For the ideal Class E amplifier where no loss is included in the circuit or device, 100% drain efficiency can be achieved. Class E is a typical class of amplifiers used in the outphasing configuration.

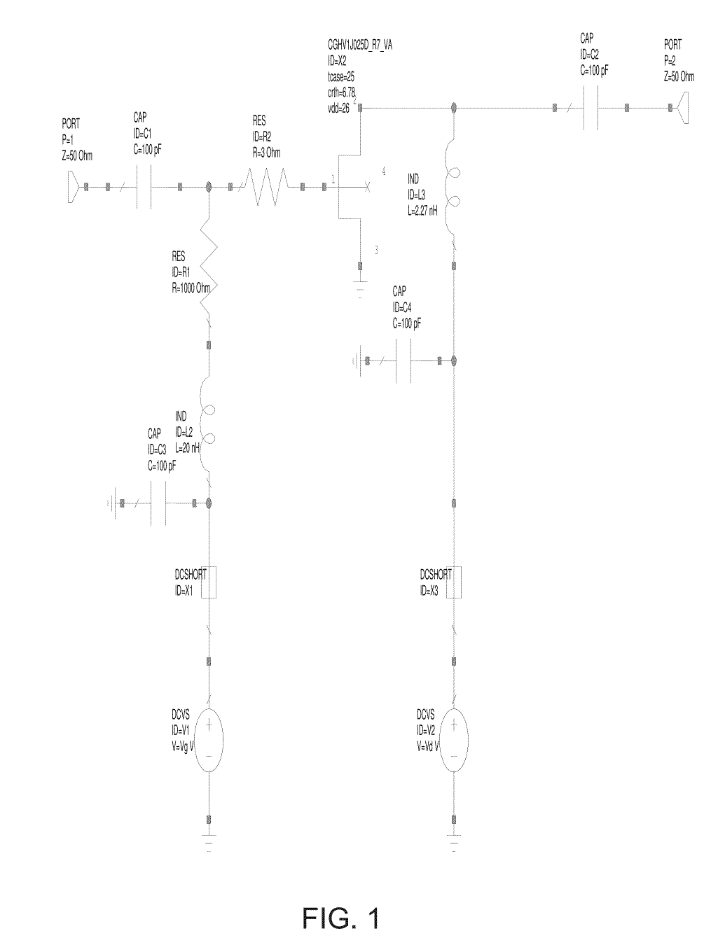

FIG. 1 illustrates a circuit diagram of one example of a Class E amplifier designed for 40 W peak power at 2 GHz. It is a parallel-circuit Class E amplifier and the output capacitance of the transistor is used as a shunt capacitance as part of the output circuit.

When the output power or its envelope changes as much as 10 dB, the optimum output impedance for best efficiency will change dramatically. If the output load impedance stays constant while the power level is changing, it gives rise to inefficiencies of the amplifier. This is one reason that traditional power amplifiers fail to maintain high efficiency under varying power levels.

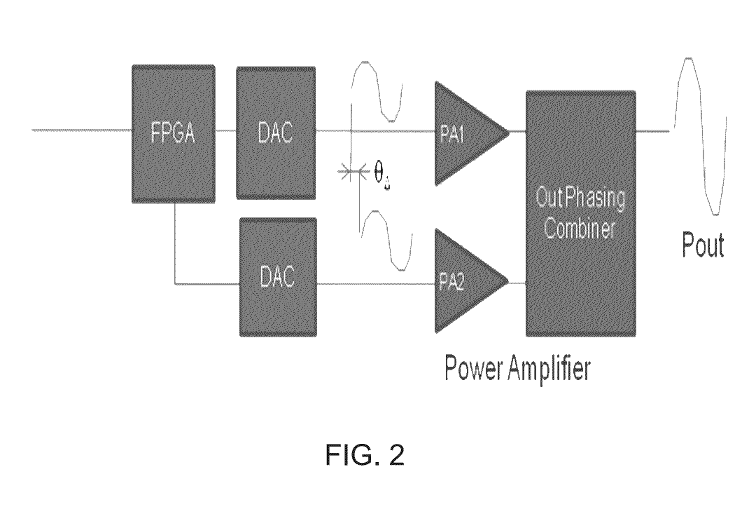

Outphasing amplifiers [1] provide a mechanism that modifies the output impedance seen by the outphasing amplifier as the envelope of the signal changes. In an outphasing amplifier circuit, two amplifiers operating at maximum power are combined through a low-loss combiner (FIG. 2).

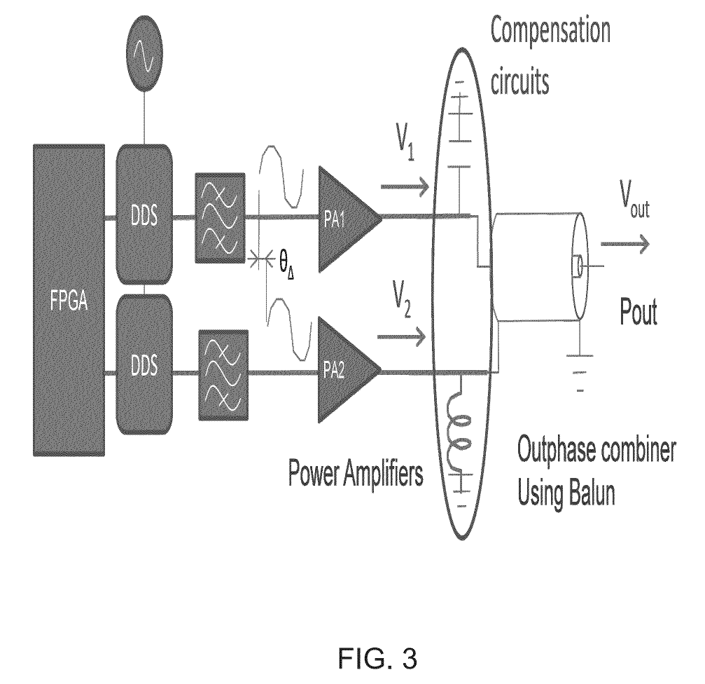

The combiner illustrated in FIG. 2 can be made from a balun as shown in FIG. 3, which can demonstrate an extremely large bandwidth (octave or more) when it is made from a section of a coaxial line with a ferrite sleeve.

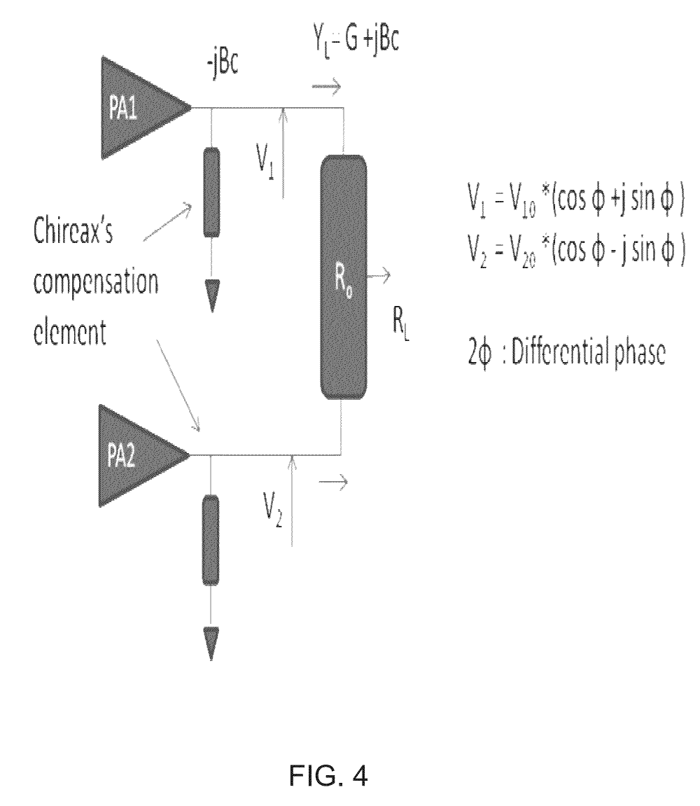

FIG. 4 is an equivalent circuit of this outphasing amplifier where two amplifiers are generating signals V₁ and V₂, having differential phase 2*φ from each other. Here PA1 is the power amplifier in the leading phase (φ) and PA2 is the one in the lagging phase (−φ), and V₁ and V₂ are node voltages associated with PA1 and PA2.

The combining circuit will present load Y_{L} to the amplifier which can be represented by Y_{L}=G_{L}+jBc, where Bc is compensated by the Chireix's elements (Bch=−Bc) as shown in FIG. 4. On the lagging phase path, Bc has an opposite sign to the leading phase path; therefore these Chireix components are asymmetric. Chireix's asymmetric components added in the combiner can improve the back-off efficiency of the outphasing amplifier further.

When the amplitude of these signals are equal (V₁₀=V₂₀), this is a traditional outphasing amplifier. Derivation of some of the key parameters of the outphasing amplifier as a function of differential phase φ is represented by the Equations below. Equations (5) and (6) are real and imaginary parts of the load admittance as a function of differential phase φ. Equation (7) is combined output power as a function of differential phase φ.

$$\begin{matrix}{I}_{o} = ( {V}_{1} - {V}_{2} ) \text{/} {R}_{o} & ( 1 ) \\ {V}_{1} - {V}_{2} = 2 {V}_{10} * jsin Φ \text{/} {R}_{o} & ( 2 ) \\ {Z}_{L} = ( {V}_{1} - {V}_{2} ) \text{/} {I}_{o} = {R}_{o} \text{/} 2 * ( 1 - jcot Φ ) & ( 3 ) \\ \begin{matrix}{Y}_{L} = 1 \text{/} {Z}_{L} \\ = {G}_{L} + j B c \\ = 2 \text{/} {R}_{o} * ( {sin}^{2} Φ + j sin 2 Φ )\end{matrix} & ( 4 ) \\ {G}_{L} = 2 \text{/} {R}_{o} * {sin}^{2} Φ & ( 5 ) \\ B c = 2 \text{/} {R}_{o} * sin 2 Φ & ( 6 ) \\ \begin{matrix}P o u t = \frac{1}{2} * {\vert {V}_{1} - {V}_{2} \vert}^{2} * {G}_{L} \\ = 4 {V}_{10}^{2} \text{/} R o * {sin}^{4} Φ\end{matrix} \\ ( o r = 2 {V}_{10}^{2} {sin}^{2} Φ * {G}_{L} ) & ( 7 )\end{matrix}$$

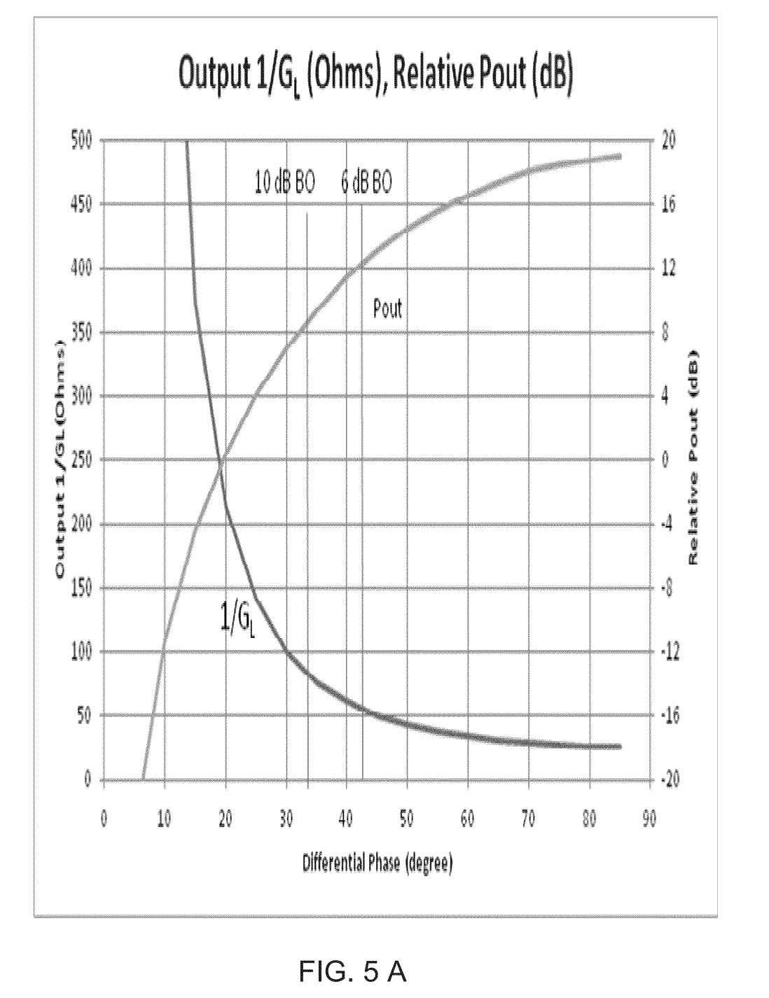

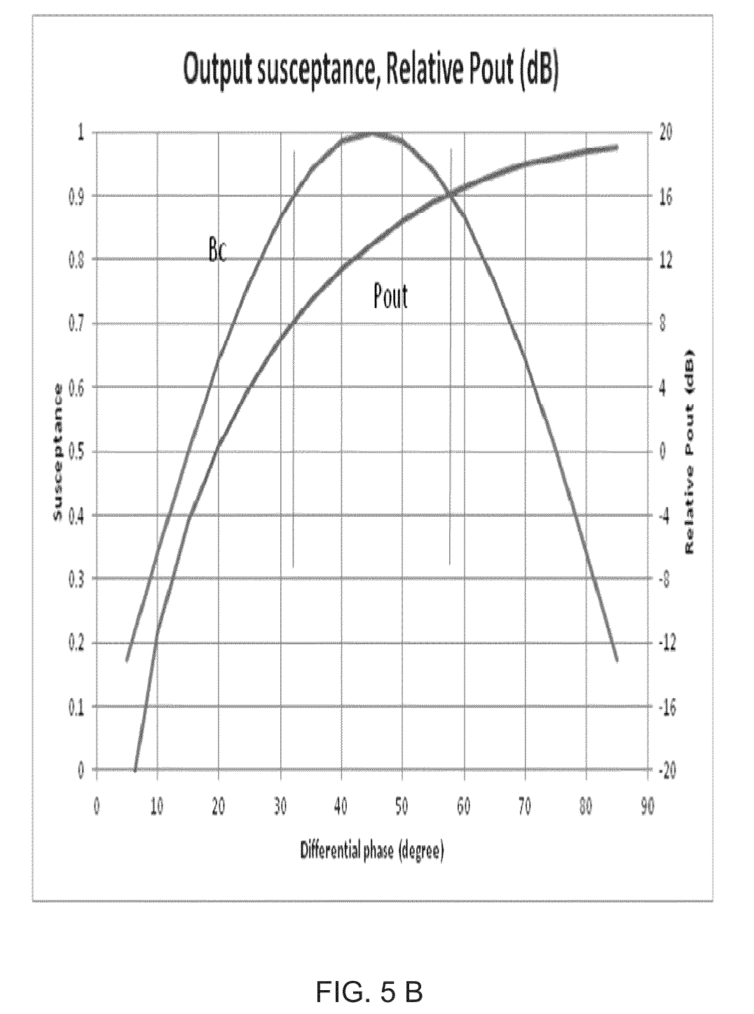

Inverse of output conductance (1/GL, Eq. 5) and output power (Eq. 7) are plotted in FIG. 5 as a function of differential phase φ. It can be seen that when φ is 90 degrees and V₁₀=V₂₀, 1/G approaches to 1 (normalized) and maximum combining is achieved. When φ approaches to 0 degrees, the combined power is reduced as the real part of the load (1/G) of the outphasing amplifier increases.

The Imaginary part of the admittance Bc(ω, φ) (Eq. 6) is represented in two parts, Bf(ω) and Bco(φ), as

Bc(ω,φ)=Bf(ω)*Bco(φ) (8)

The first part, Bf(ω), represents the frequency sensitive component, primarily derived from the parasitic components in the combiner, and the second part Bco(φ) is the frequency independent component derived from ideal outphasing structure shown in FIG. 4. As plotted in FIG. 5, the Imaginary part of the admittance Bc(ω, φ) reaches maximum at φ=45, while Bc(ω,φ) becomes minimum at φ=0, 90.

The reactive component Bc(ω, φ) presented by the combiner circuit is partially cancelled by introducing Chireix compensation components (Bch=−Bc), which could be capacitive or inductive. These compensation circuits can be designed to provide a match between the amplifier and combiner to better improve efficiency of the outphasing amplifier at backoff. However Bch does not behave the same way as Bc with respect to frequency ω. It is does not vary with differential phase φ. Therefore the compensation is only effective at a particular frequency and within a limited range of φ.

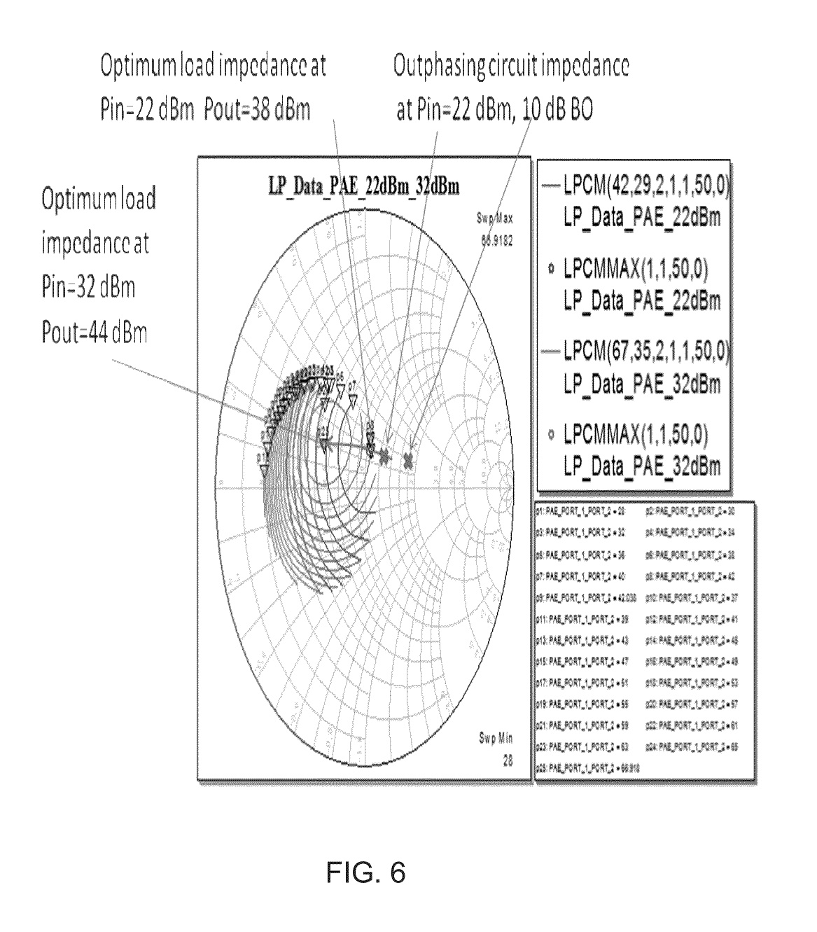

The load impedance contours for the power added efficiency are plotted in FIG. 6 for two drive power levels, Pin 32 dBm and 22 dBm, showing peak efficiency at 67% and 42% respectively. The output power from the amplifier at these power levels is 44 dBm (the peak) and 38 dBm (6 dB back-off) respectively. The load impedance contours are shown for a constant efficiency at 4% intervals from the peak. As can be seen, the real part of the optimum impedance moves from 0.6 (normalized to 50 ohms) at Pin=32 dBm to 1 at Pin=22 dBm. FIG. 6 also shows that the impedance presented by the outphasing circuit to the amplifier, which can be calculated from Equations (5) and (6) by changing the differential phase from 0 to 90 degrees, corresponding to the output power from the minimum and the maximum. To accomplish 6 dB output power back-off from the peak, the differential phase will be changed from 90 to 42 degrees, which moves the real part of the impedance from 25 ohms to 52 ohms as shown by the x in FIG. 6. The agreement between the device impedance and the outphasing load impedance is good in between these power levels, providing an efficient operation of the amplifier in this power level range. However, the divergence between the device impedance and the outphasing load impedance becomes larger when the drive level becomes smaller, because, the outphasing load impedance increases rapidly as the power level continues to decrease as shown in FIG. 6. On the other hand, the device impedance does not move as much in the small power levels.

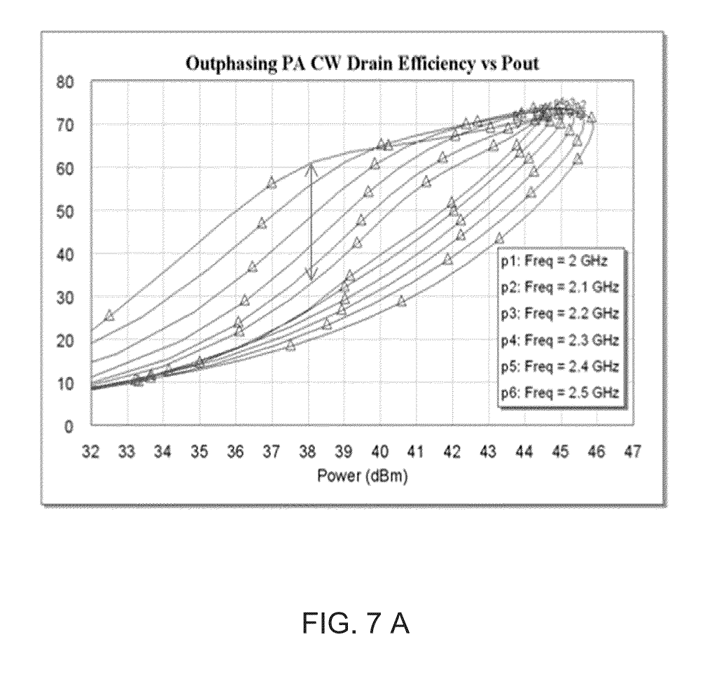

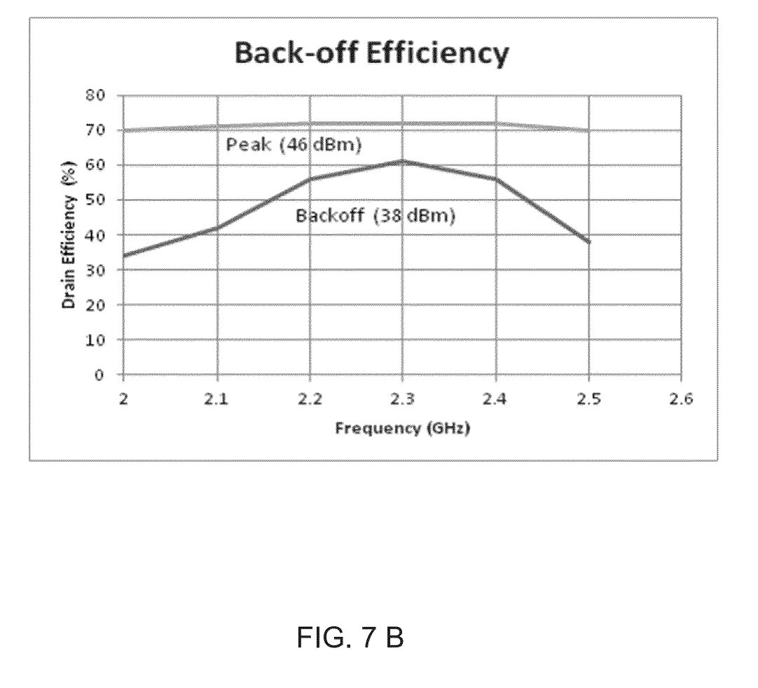

FIG. 7 shows drain efficiency of the outphasing amplifier as a function of output power of the outphasing amplifier at different frequencies ranging from 1.9 GHz to 2.5 GHz. It is obvious that the peak efficiency stays high within this frequency band near the maximum output power condition. However, when the power level is backed off, the efficiency has much more frequency dependency and it ranges from 33% to 60% at 38 dBm output power over the same frequency range.

Large variation of efficiency of the outphasing amplifier at backoff power levels (i.e. 38 dBm) is due to dependency of the reactive component (Bc+Bch) on w and φ as described in Equation 8. As described, the Chireix components Bch only compensate the reactive part of the combining circuit, Bc, at particular ω and φ. Large compensation of Bc by Bch will make the mismatch large when it is out of the compensated condition when w and φ are shifted. Making the circuit with minimum Bc will require smaller compensation by Bch, therefore reduce the frequency dependency.

The proposed invention is concerned with maximizing the bandwidth of the outphasing amplifier by the use of a combination of signal conditioning of two signals injected into two amplifiers, different bias conditions for the two amplifiers, and different size amplifiers. As will be disclosed herein, the different/non-symmetrical operating conditions for two amplifiers can be provided by any combination of: different drive powers provided to the two amplifiers; biasing the two amplifiers differently; using different sized amplifiers; and for pulsed amplifiers, providing different pulse widths to the amplifiers

A set of equations were derived that describe the load condition Z_{L} when V₂₀ is not equal to V₁₀ as shown below.

$$\begin{matrix}{Z}_{L} = 1 / {Y}_{L} = 1 / ( {G}_{L} + jB c o ) & ( 9 ) \\ {Z}_{L} = {R}_{o} * ( \frac{α {cos}^{2} φ + β {sin}^{2} φ}{{α}^{2} {cos}^{2} φ + {β}^{2} {sin}^{2} φ} + j \frac{( α - β ) sin φ * cos φ}{{α}^{2} {cos}^{2} φ + {β}^{2} {sin}^{2} φ} ) & ( 10 ) \\ α = 1 - ( \frac{{V}_{20}}{{V}_{10}} ) , β = 1 + ( \frac{{V}_{20}}{{V}_{10}} ) & ( 11 )\end{matrix}$$

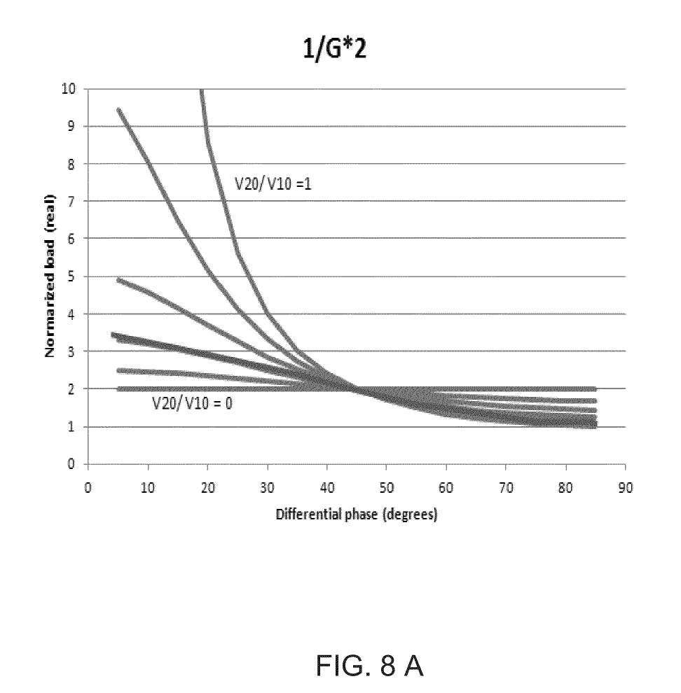

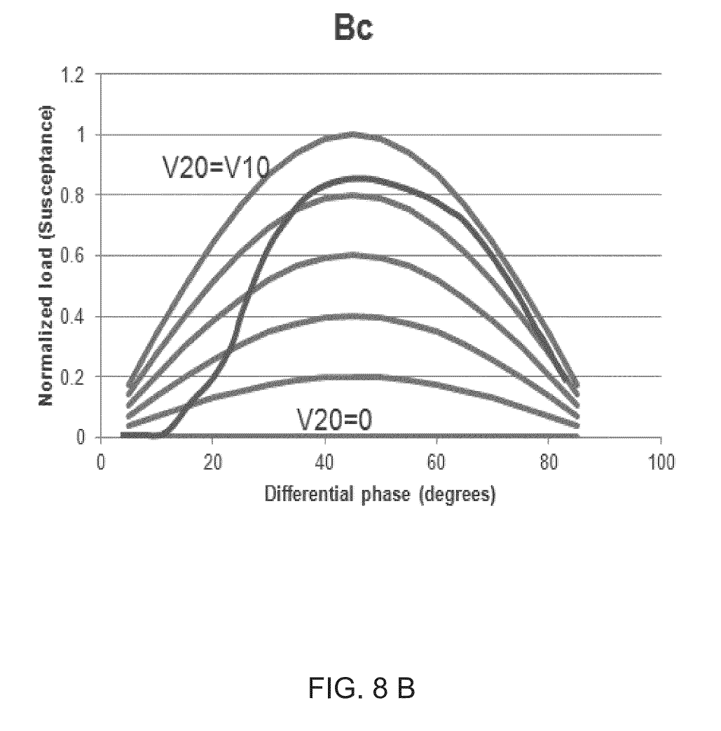

The real and imaginary parts of the output load are plotted in FIG. 8 (Left: 1/GL, Right: Bc) as a function of V₂₀/V₁₀. When V₂₀/V₁₀=1, the equations render themselves to Equations (5) and (6). When V₂₀/V₁₀<1, variation of the real part of the load (1/GL) is much smaller when differential phase difference φ is near 0. The peaks of both 1/GL and Bc are both reduced. It is expected that lowering the ratio of V₂₀/V₁₀ would reduce the frequency dependency of the output power because of lower peaks of both 1/GL and Bc. However, lower the ratio of V₂₀/V₁₀ would reduce the maximum power when two powers are fully combined.

By selecting V₂₀/V₁₀ for the optimum load condition at each differential phase setting, the load impedance can be maintained at the optimum at all output power levels. The red line shown in the FIG. 8 is an example of optimum condition at all power levels having varying ratio of output voltages V₂₀/V₁₀ at different power conditions.

By limiting the ratio of V₂₀/V₁₀ to 0.4, the variation in the real part of the Normalized load is limited to less than about 3.5 when the differential phase φ is small (i.e. 0). This load conditions is much closer to the optimum efficiency condition at low output power. A dynamic range for high efficiency can be extended to lower power region by selecting V₂₀/V₁₀<1 when output power requirement is small. If the amplitude V₂₀ is kept constant and equal to V₁₀ (V₂₀/V₁₀=1) when the differential phase is small, the real part of the Normalized load would be very large (>10), resulting with low efficiency at this power level.

As can be seen in the FIG., Bc also varies a function of the ratio of V₂₀/V₁₀ and the variation can be reduced by selecting smaller value for the ratio of V₂₀/V₁₀. Smaller ratios of V₂₀/V₁₀ will require smaller compensation circuit (smaller Bch), and thus less sensitive to the frequency.

The nonsymmetrical ratio of drive voltage (V₂₀ not equal to V₁₀) between the two amplifiers of the outphasing combiner can be achieved in at least three ways and any combination of them. Namely, as will be disclosed herein, the different/non-symmetrical operation of two amplifiers can be provided by any combination of: different drive powers provided to the two amplifiers; biasing the two amplifiers differently; and using different sized amplifiers.

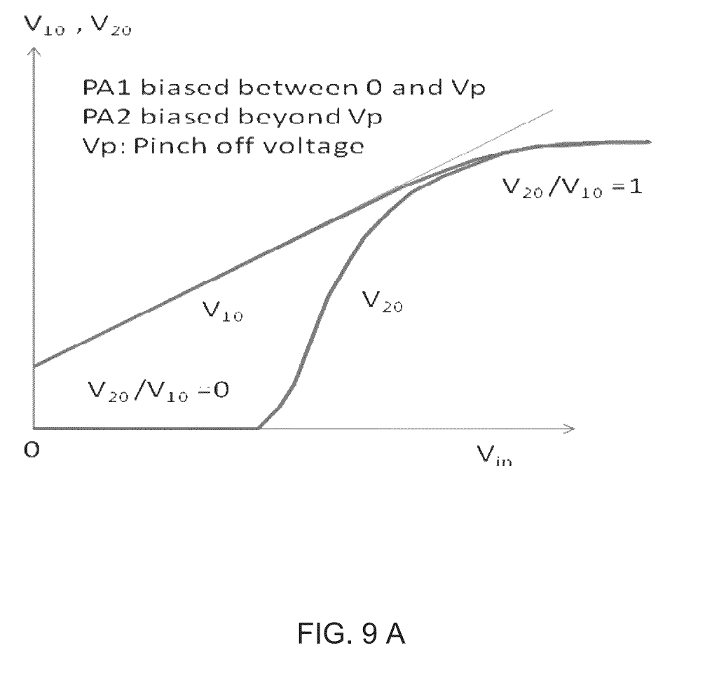

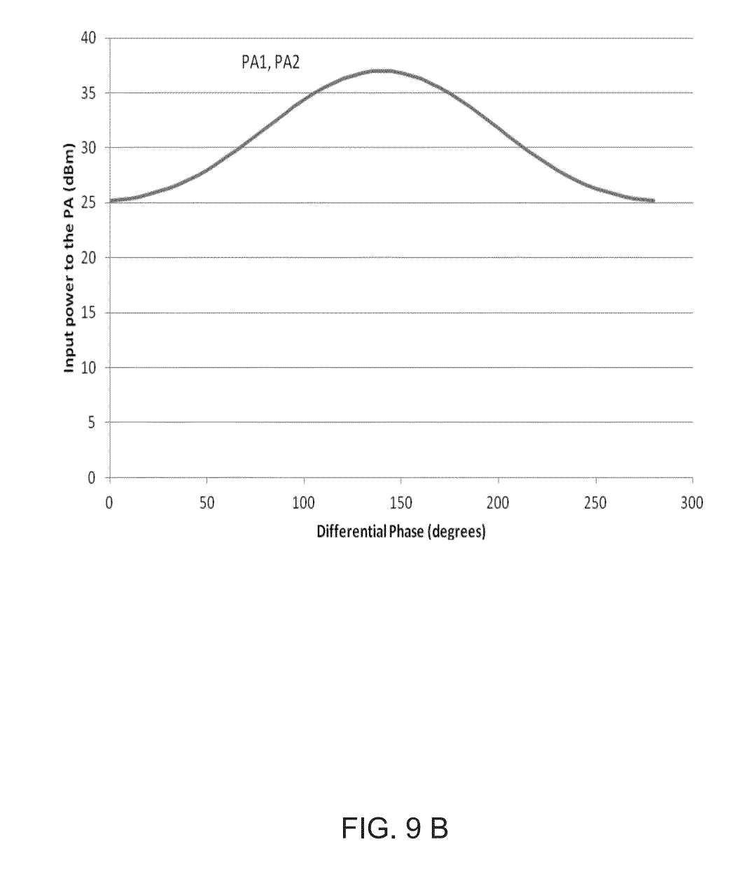

A first approach is to use different drive powers for each amplifier, as described above, to optimize for bandwidth and efficiency. In this approach, the input powers to these amplifiers are controlled independently to generate asymmetrical drive by command. FIG. 9 schematically shows the drive level of amplifiers as a function of input signal levels. V₁₀ in the leading phase (PA1) amplifier will maintain saturated power level while V₂₀ in the lagging phase (PA2) will have reduced input power at back-off.

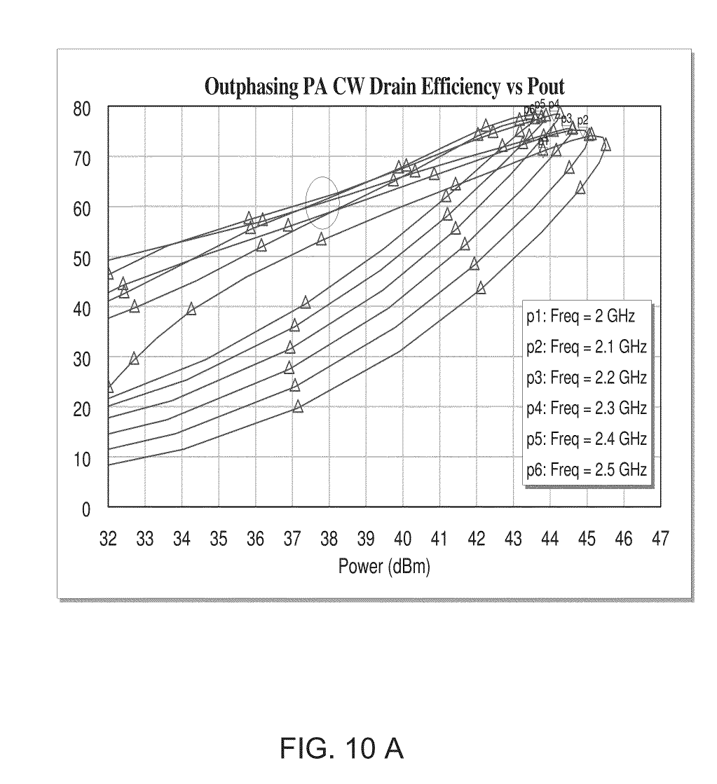

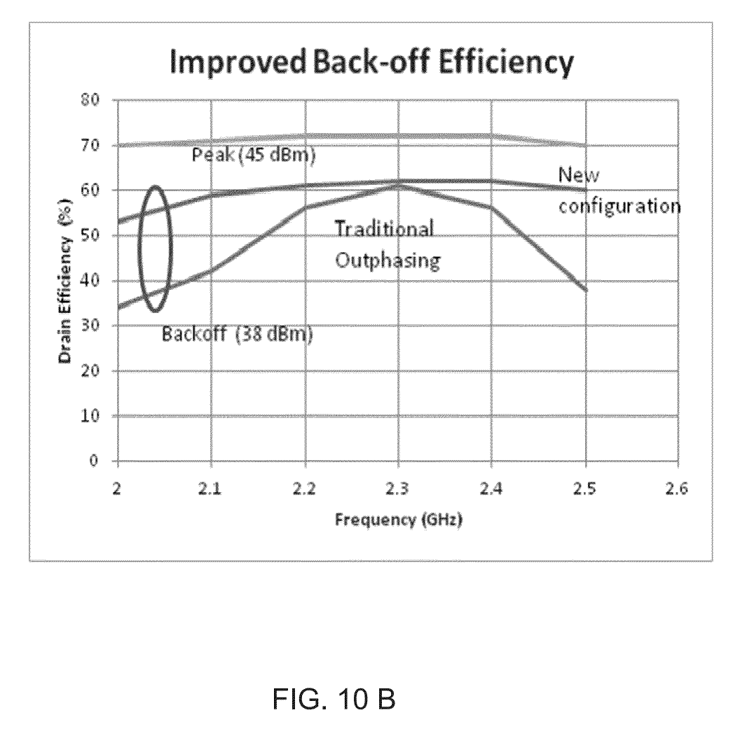

FIG. 10 shows the impact of input control to the two amplifiers on the back-off efficiency over a frequency band. Contrary to the original case shown in FIG. 7 where two drive powers are kept equal, the efficiency is maintained over 60% in the frequency band of 2.1 to 2.5 GHz at the back-off level of 38 dBm Pout.

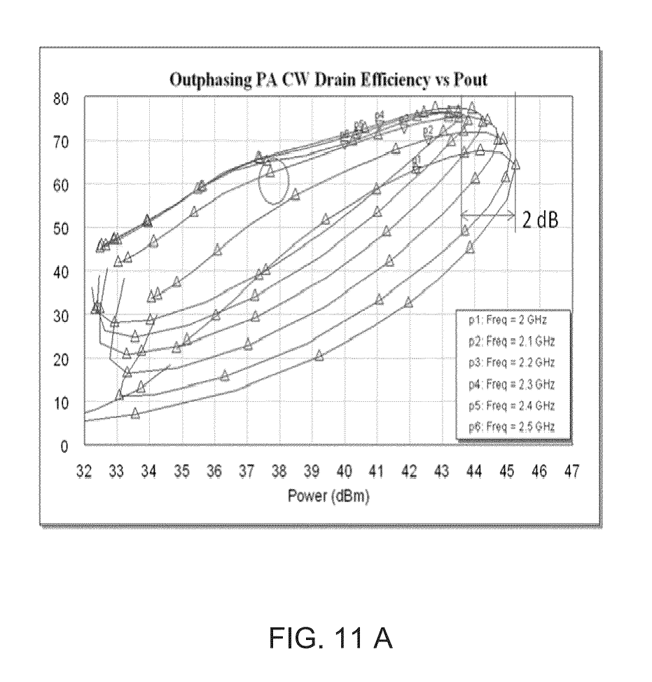

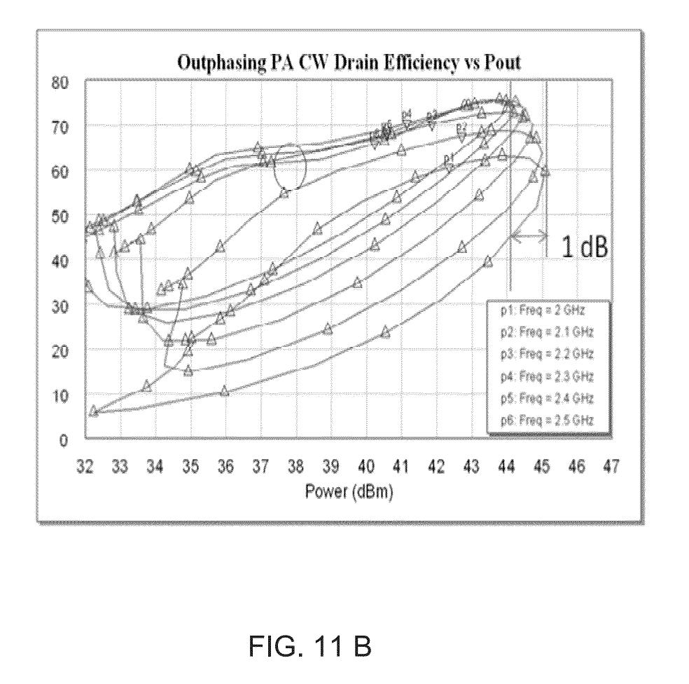

A second approach is to set the amplifiers to different bias conditions. One example of this approach is to bias the PA2 in hard pinch-off (more negative gate voltage) that shuts off the signal amplification of PA2 when the signal level is low, making V₂₀=0. PA1 is biased at a less negative gate voltage, so that PA1 is active at low input power. Both amplifiers are designed with the proper output matching circuit for Class E operation. When the input signals to these amplifiers are at or below a cut-off level, V₂₀/V₁₀ will be small and approaches to 0 when drive level is really small. When the signal level is increased beyond the cutoff level, V₂₀ will increase and at the full power drive, V₂₀/V₁₀ will approach 1. Therefore, V₂₀/V₁₀ will vary between 0 and 1 depending on the input signal power level and the bias voltages to the amplifiers. FIG. 11 shows the asymmetric output signal levels (left) as a function of drive power level (right) in this embodiment, having the different bias conditions set at pinch-off for PA1 and above pinch-off for PA2.

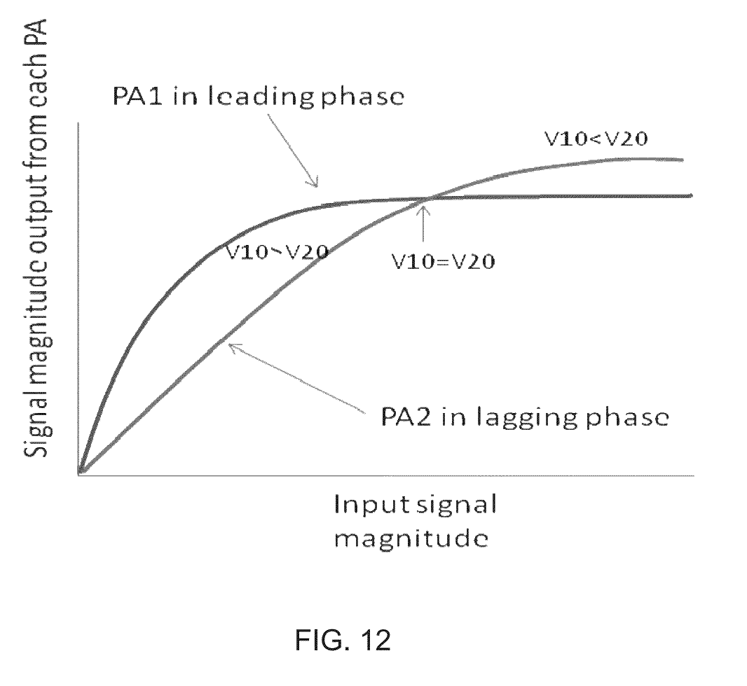

A third approach is to use different sizes of amplifiers for PA1 and PA2 in the leading and lagging phase paths, respectively. As a result, there will be asymmetric output power signals from the PA1 and PA2 going into the combiner, even when the input power and/or bias conditions is symmetric to the two amplifiers PA1 and PA2. These asymmetric output power characteristics are shown in FIG. 12 as a function of input signal magnitude. In this embodiment, a smaller amplifier is used for PA1 compared to PA2. Therefore, when amplifiers are driven at high power, PA2 delivers higher power than PA1. At back-off, the signal level is controlled to produce asymmetric signal levels at output of these amplifiers as shown in the FIG. The different saturated power levels of the two amplifiers yield a wider dynamic range of operation of the outphasing amplifier.

According to aspects of some embodiments for a pulse driven implementation of the outphasing amplifier, the asymmetric input signal control can also be implemented in a pulse driven outphasing amplifier by changing the pulse width of the pulse signals applied to each of the amplifiers PA1 and PA2 of the outphasing amplifier independently. This is a very flexible method which maintains high efficiency over a wide dynamic range for wideband operation.

Having described preferred embodiments which serve to illustrate various concepts, circuits, and techniques which are the subject of this patent, it will now become apparent to those of ordinary skill in the art that other embodiments incorporating these concepts, circuits, and techniques may be used. For example, described herein are specific exemplary circuit topologies and specific circuit implementations for achieving a desired performance. It is recognized, however, that the concepts and techniques described herein may be implemented using other circuit topologies and specific circuit implementations. Accordingly, it is submitted that that scope of the patent is not limited to the described embodiments, but rather should be limited only by the spirit and scope of the following claims.

What is claimed is:

1. A method of operating an outphasing amplifier comprising first and second amplifiers to achieve wider bandwidth and higher efficiency operation of the outphasing amplifier, comprising:
controlling input signal levels to each of the first and second amplifiers independently and asymmetrically to achieve nonsymmetrical drive to each of the first amplifier and second amplifier of the outphasing amplifier.

2. The method of claim 1, further comprising providing the first and second amplifiers in the outphasing amplifiers as different sized amplifiers.

3. The method of claim 2, further comprising independently adjusting a gate bias of each the first and second amplifiers so that a leading phase amplifier is more pinched off and a lagging phase amplifier is less pinched off.

4. The method of claim 1, further comprising independently adjusting a gate bias of each the first and second amplifiers so that a leading phase amplifier is more pinched off and a lagging phase amplifier is less pinched off.

5. The method of claim 1, further comprising independently controlling input pulse widths of a first input signal to the first amplifier and a second input signal to the second amplifier to achieve nonsymmetrical drive to the first amplifier and the second amplifier of the outphasing amplifier.

6. The method of claim 5, further comprising providing the first amplifier and the second amplifier in the outphasing amplifier with different sizes.

7. A method of operating an outphasing amplifier comprising first and second amplifiers to achieve wider bandwidth and higher efficiency operation of the outphasing amplifier, comprising:
independently adjusting a gate bias of the first amplifier and the second amplifier so that a leading phase amplifier is more pinched off and a lagging phase amplifier is less pinched off to achieve nonsymmetrical drive to the first amplifier and the second amplifier of the outphasing amplifier.

8. The method of claim 7, further comprising providing the first amplifier and the second amplifier in the outphasing amplifier with different sizes.

9. The method of claim 8, further comprising controlling input signal levels to each of the first and second amplifiers independently and asymmetrically to achieve nonsymmetrical drive to each of the first amplifier and second amplifier of the outphasing amplifier.

10. The method of claim 7, further comprising controlling input signal levels to each of the first and second amplifiers independently and asymmetrically to achieve nonsymmetrical drive to each of the first amplifier and second amplifier of the outphasing amplifier.

11. The method of claim 7, further comprising independently controlling input pulse widths of a first input signal to the first amplifier and a second input signal to the second amplifier to achieve nonsymmetrical drive to the first amplifier and the second amplifier of the outphasing amplifier.

12. The method of claim 11, further comprising providing the first amplifier and the second amplifier in the outphasing amplifier with different sizes.

13. A method of operating a pulse-driven outphasing amplifier comprising first and second amplifiers to achieve wider bandwidth and higher efficiency operation of the pulse-driven outphasing amplifier, comprising:
independently controlling input pulse widths of a first input signal to the first amplifier and a second input signal to the second amplifier to achieve nonsymmetrical drive to the first amplifier and the second amplifier of the outphasing amplifier.

14. The method of claim 13, further comprising independently adjusting a gate bias of the first amplifier and the second amplifier so that a leading phase amplifier is more pinched off and a lagging phase amplifier is less pinched off to achieve nonsymmetrical drive to the outphasing amplifier.

15. The method of claim 13, further comprising providing the first amplifier and the second amplifier in the outphasing amplifiers with different sizes.
